(19) United States
(12) Patent Application Publication
(10) Pub. No.: US 2025/0336818 A1
(43) Pub. Date: Oct. 30, 2025

(54) METAL PILLARS PREVENTING WETTING ON SIDEWALLS AND METHOD FORMING SAME

(71) Applicant: Taiwan Semiconductor Manufacturing Co., Ltd., Hsinchu (TW)

(72) Inventors: Po-Chen Lai, Hsinchu (TW); Ming-Chih Yew, Hsinchu (TW); Li-Ling Liao, Hsinchu (TW); Shu-Shen Yeh, Taoyuan City (TW); Shin-Puu Jeng, Hsinchu (TW)

(21) Appl. No.: 19/262,726

(22) Filed: Jul. 8, 2025

Related U.S. Application Data
(62) Division of application No. 17/805,034, filed on Jun. 2, 2022.

(51) Int. Cl. H01L 23/528; H01L 21/768; H01L 23/00

(52) U.S. Cl. CPC H01L 23/5283; H01L 21/76873; H01L 24/11; H01L 24/14; H01L 24/17; H01L 2224/11462; H01L 2224/13023

(57) ABSTRACT

A package includes a first package component, which includes a bottom dielectric layer, a micro-bump protruding below the bottom dielectric layer, and a metal pillar protruding below the bottom dielectric layer. The metal pillar has a top width and a bottom width greater than the top width. The package further includes a die underlying and bonding to the micro-bump, a solder region underlying and joining to a bottom surface of the metal pillar, and a second package component underlying the first package component. The second package component includes a conductive feature underlying and joining to the solder region.

### PRIORITY CLAIM AND CROSS-REFERENCE

This application is a divisional of U.S. patent application Ser. No. 17/805,034, filed Jun. 2, 2022, which application is hereby incorporated herein by reference in its entirety.

### BACKGROUND

In the packaging of integrated circuits, a plurality of device dies may be bonded to a redistribution structure. Device dies and Independent Passive Devices (IPDs) may be bonded to the same redistribution structure. The IPDs may be disposed between package components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14 illustrate the cross-sectional views of intermediate stages in the formation of a package in accordance with some embodiments.

FIGS. 15-18 illustrate the cross-sectional views of intermediate stages in the formation of a package in accordance with some embodiments.

FIGS. 19 and 20 illustrate the cross-sectional views of intermediate stages in the bonding of package components in accordance with some embodiments.

FIGS. 21A, 21B, and 21C illustrate a cross-sectional view, a perspective view, and a top view, respectively, of a metal pillar having a conical shape in accordance with some embodiments.

FIGS. 22A, 22B, and 22C illustrate a cross-sectional view, a perspective view, and a top view, respectively, of a metal pillar having steps in accordance with some embodiments.

FIGS. 23A, 23B, and 23C illustrate a cross-sectional view, a perspective view, and a top view, respectively, of a metal pillar having an oval conical shape in accordance with some embodiments.

FIGS. 24A, 24B, and 24C illustrate a cross-sectional view, a perspective view, and a top view, respectively, of a metal pillar having a pyramidal frustum shape in accordance with some embodiments.

FIG. 25 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, the package includes metal pillars, which have lower portions wider than respective upper portion. The metal pillars in accordance with the embodiments of the present disclosure are difficult for solder region to wet on their sidewalls. Accordingly, the standoff heights of the solder regions that are on the metal pillars are increased, thus allowing enough space for Independent Passive Devices (IPDs) to be allocated therein. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

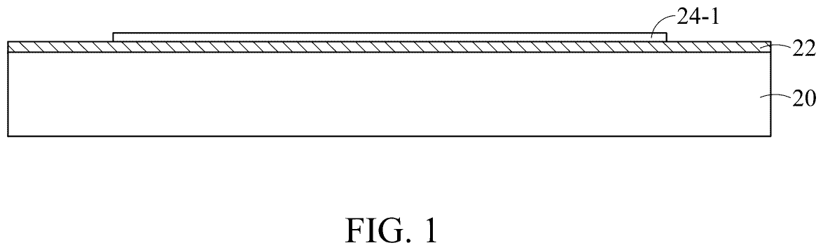

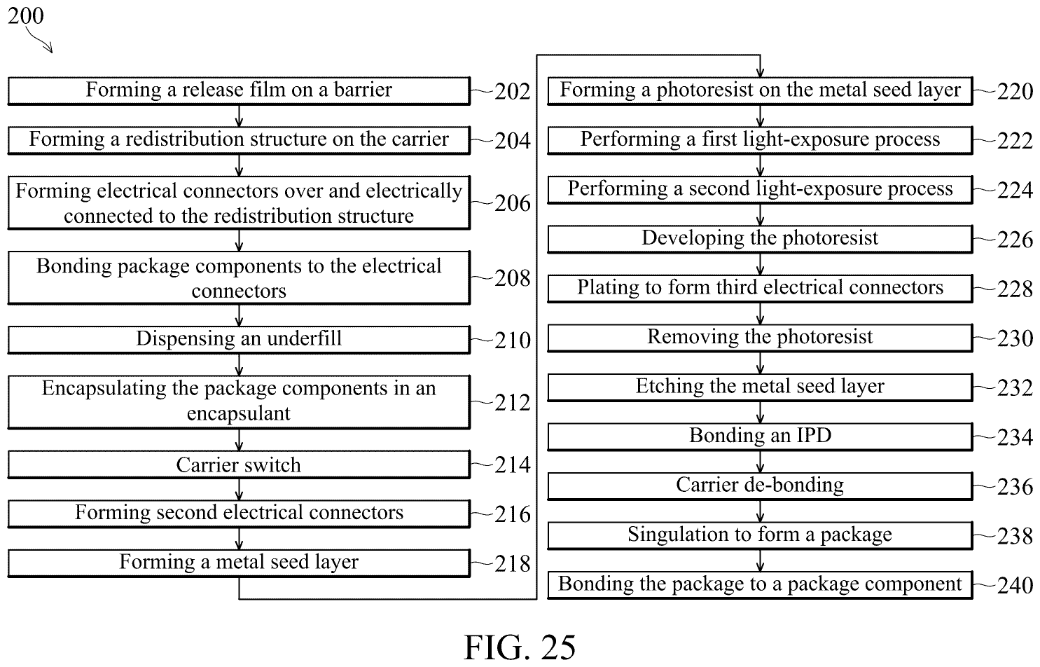

FIGS. 1 through 14 illustrate the cross-sectional views of intermediate stages in the formation of a package in accordance with some embodiments of the present disclosure. The corresponding processes are also reflected schematically in the process flow shown in FIG. 25.

FIG. 1 illustrates the formation of release film 22 on carrier 20. The respective process is illustrated as process 202 in the process flow 200 as shown in FIG. 25. Carrier 20 may be a glass carrier, a silicon wafer, an organic carrier, or the like. Carrier 20 may have a round top-view shape in accordance with some embodiments. Release film 22 may be formed of a polymer-based material and/or an epoxy-based thermal-release material (such as a Light-To-Heat-Conversion (LTHC) material), which is capable of being decomposed under radiation such as a laser beam, so that carrier 20 may be de-bonded from the overlying structures that will be formed in subsequent processes. In accordance with some embodiments of the present disclosure, release film 22 is applied on carrier 20 through coating.

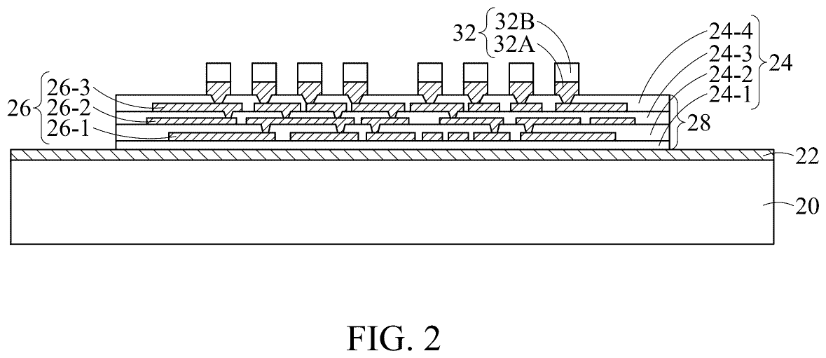

A redistribution structure 28, which includes a plurality of dielectric layers 24 and a plurality of RDLs 26, is formed over the release film 22, as shown in FIGS. 1 and 2. The respective process is illustrated as process 204 in the process flow 200 as shown in FIG. 25. Referring to FIG. 1, a first dielectric layer 24-1 is formed on release film 22. In accordance with some embodiments of the present disclosure, dielectric layer 24-1 is formed of or comprises an organic material, which may be a polymer. The organic material may also be a photo-sensitive material. For example, dielectric layer 24-1 may be formed of or comprises polyimide, polybenzoxazole (PBO), benzocyclobutene (BCB), or the like.

Referring to FIG. 2, a first plurality of Redistribution Lines (RDLs) 26 (denoted as 26-1) are formed on dielectric layer 24-1. The formation of RDLs 26-1 may include forming a metal seed layer (not shown) over dielectric layer 24-1, forming a patterned mask (not shown) such as a photoresist over the metal seed layer, and then performing a metal plating process to deposit a metallic material on the exposed metal seed layer. The patterned mask and the portions of the metal seed layer covered by the patterned mask are then removed, leaving RDLs 26-1 as shown in FIG. 1. In accordance with some embodiments of the present disclosure, the metal seed layer includes a titanium layer and a copper layer over the titanium layer. The metal seed layer may be formed using, for example, Physical Vapor Deposition (PVD) or a like process. The plating may be performed using, for example, an electrochemical plating process.

FIG. 2 further illustrates the formation of additional dielectric layers 24-2, 24-3, and 24-4, for example, and additional RDLs 26-2 and 26-3, for example. Throughout the description, dielectric layers 24-1, 24-2, 24-3, and 24-4 are individually and collectively referred to as dielectric layers 24, and RDLs 26-1, 26-2, and 26-3 are individually and collectively referred to as RDLs 26. In accordance with some embodiments, dielectric layer 24-2 is first formed on RDLs 26-1. The bottom surface of dielectric layer 24-2 is in contact with the top surfaces of RDLs 26-1 and dielectric layer 24-1. Dielectric layer 24-2 may be formed of or comprise an organic dielectric material, which may be a polymer. For example, dielectric layer 24-2 may comprise a photo-sensitive material such as PBO, polyimide, BCB, or the like. Dielectric layer 24-2 is then patterned to form via openings (occupied by the via portions of RDLs 26-2) therein. Hence, some portions of RDLs 26-1 are exposed through the openings in dielectric layer 24-2.

Next, RDLs 26-2 are formed on dielectric layer 24-2 to connect to RDLs 26-1. RDLs 26-2 include via portions extending into the openings in dielectric layer 24-2, and trace portions (metal line portions) over dielectric layer 24-2. In accordance with some embodiments, the formation of RDLs 26-2 may include depositing a blanket metal seed layer extending into the via openings, and forming and patterning a plating mask (such as a photoresist), with openings formed in the plating mask and directly over the via openings. A plating process is then performed to plate a metallic material, which fully fills the via openings, and has some portions higher than the top surface of dielectric layer 24-2. The plating mask is then removed, followed by an etching process to remove the exposed portions of the metal seed layer, which was previously covered by the plating mask. The remaining portions of the metal seed layer and the plated metallic material are RDLs 26-2. RDLs 26-2 include RDL lines (also referred to as traces or trace portions) and via portions (also referred to as vias). The trace portions are over dielectric layer 24-2, and the via portions are in dielectric layer 24-2. Each of the vias may have a tapered profile, with the upper portions wider than the corresponding lower portions.

The metal seed layer and the plated material may be formed of the same material or different materials. For example, the metal seed layer may include a titanium layer, and a copper layer over the titanium layer. The plated metallic material in RDLs 26-2 may include a metal or a metal alloy including copper, aluminum, tungsten, or the like, or alloys thereof.

After the formation of RDLs 26-2, there may be more dielectric layers and the corresponding RDLs formed, with the upper RDLs over and landing on the respective lower RDLs. For example, FIG. 2 illustrates dielectric layers 24-3 and 24-4, and RDLs 26-3 as an example. It is appreciated that there may be more or fewer dielectric layers and RDLs than illustrated. The materials of dielectric layers 24-3 and 24-4 may be selected from the same group (or different group) of candidate materials as dielectric layers 24-1 and 24-2. For example, dielectric layers 24-3 and 24-4 may be formed of an organic material, which may be a polymer such as polyimide, PBO, BCB, or the like. RDLs 26-3 may also be formed of similar materials and using similar formation processes as RDLs 26-1 and 26-2.

After the formation of a top dielectric layer such as dielectric layer 24-4, electrical connectors 32 are formed. The respective process is illustrated as process 206 in the process flow 200 as shown in FIG. 25. Electrical connectors 32 may be formed of or comprise micro-bumps, metal pads, metal pillars, Under-Bump-Metallurgies (UBMs), solder regions, and/or the like. For example, electrical connectors 32 may include metal pillars 32A and solder regions 32B in accordance with some embodiments. The formation of electrical connectors 32 may also be similar to the formation of RDLs 26-2, which formation process includes patterning the top dielectric layer to expose the underlying RDLs, forming a metal seed layer, forming a patterned plating mask, performing one or a plurality of plating processes to form metal pillars 32A, removing the plating mask, and etching the metal seed layer. When electrical connectors 32 include solder regions 32B, the solder regions 32B may be plated using the same plating mask used for plating metal pillars 32A, followed by a reflow process to round the surfaces of solder regions 32B.

Throughout the description, dielectric layers 24, RDLs 26, and electrical connectors 32 collectively form redistribution structure 28, which is alternatively referred to as interconnect component 28 or organic interposer 28.

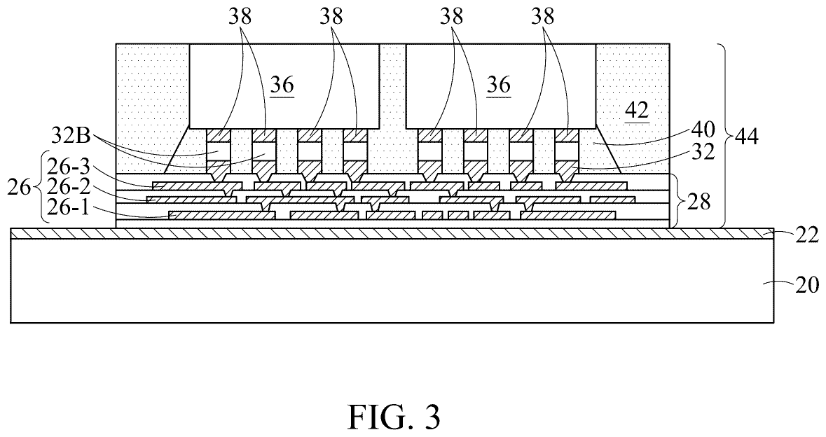

FIG. 3 illustrates the bonding of package components 36 to interconnect component 28. The respective process is illustrated as process 208 in the process flow 200 as shown in FIG. 25. Electrical connectors 38, which are the surface features of package components 36, may be bonded to metal pillars 32A through solder regions 32B in accordance with some embodiments. Electrical connectors 38 may be UBMs, metal pillars, bond pads, or the like. In accordance with alternative embodiments, electrical connectors 38 are metal pillars, and are bonded to electrical connectors 32 through direct metal-to-metal bonding, with no solder regions therebetween.

In accordance with some embodiments, package components 36 include a plurality of groups of package components, with the groups being identical to each other. Each of the groups may be a single-component group or a multi-component group. For example, FIG. 3 illustrates an example in which each group includes two package components 36. In accordance with some embodiments, package components 36 include a logic die, which may be a Central Processing Unit (CPU) die, a Graphic Processing Unit (GPU) die, a mobile application die, a Micro Control Unit (MCU) die, an input-output (IO) die, a BaseBand (BB) die, an Application processor (AP) die, or the like. Package components 36 may also include memory dies such as Dynamic Random-Access Memory (DRAM) dies, Static Random-Access Memory (SRAM) dies, or the like. The memory dies may be discrete memory dies, or may be in the form of a die stack that includes a plurality of stacked memory dies. Package components 36 may also include System-on-Chip (SOC) dies.

Underfill 40 is dispensed into the gaps between package components 36 and interconnect component 28. The respective process is illustrated as process 210 in the process flow 200 as shown in FIG. 25. Underfill 40 may also be dispensed between neighboring package components 36 that are in the same group of package components. In accordance with some embodiments, underfill 40 includes a base material and filler particles mixed in the base material. The base material may be a resin, an epoxy, and/or a polymer. Some example base materials include epoxy-amine, epoxy anhydride, epoxy phenol, or the like, or combinations thereof. The filler particles may be formed of a dielectric material, and may include silica, alumina, boron nitride, or the like, which may be in the form of spherical particles. Underfill 40 is dispensed in a flowable form, and is then cured. In accordance with alternative embodiments, underfill 40 is formed of a non-conductive film, which is dispensed on interconnect component 28 first, and package components 36 are pressed against interconnect component 28, so that the electrical connectors in package components 36 penetrate through the non-conductive film to contact electrical connectors 32.

Next, package components 36 are encapsulated in encapsulant 42. The respective process is illustrated as process 212 in the process flow 200 as shown in FIG. 25. Encapsulant 42 may include a molding compound, a molding underfill, an epoxy, and/or a resin. In a subsequent process, a planarization process such as a Chemical Mechanical Polish (CMP) process or a mechanical grinding process is performed to polish encapsulant 42. Package components 36 may be exposed as a result of the planarization process. For example, when package components 36 comprise semiconductor substrates, the semiconductor substrates may be exposed. Throughout the description, the features over release film 22, which features include interconnect structure 28, package components 36, underfill 40, and encapsulant 42, are collectively referred to as reconstructed wafer 44.

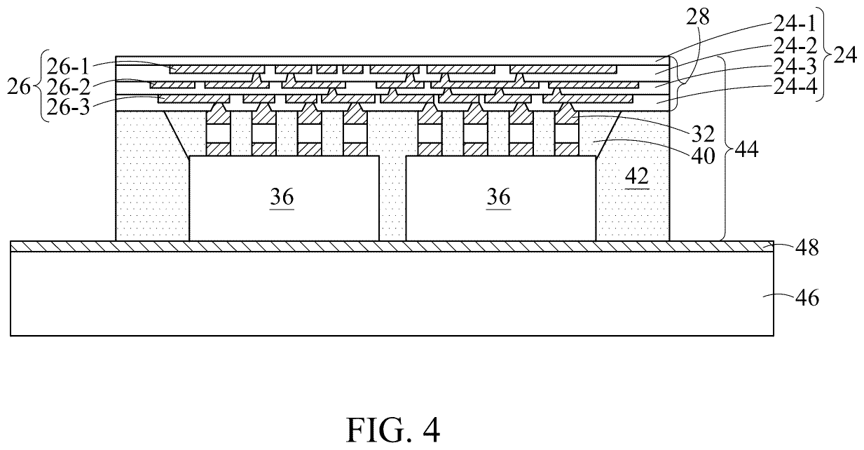

FIG. 4 illustrates a carrier switch process. The respective process is illustrated as process 214 in the process flow 200 as shown in FIG. 25. First, carrier 46 is adhered to an opposite side of the reconstructed wafer 44 than carrier 20. Release film 48, which may also comprise a thermal release film such as an LTHC, is used to adhere carrier 46 to reconstructed wafer 44. The reconstructed wafer 44 is then de-bonded from carrier 20, for example, by projecting UV light or a laser beam, which penetrates through carrier 20, on release film 22. Release film 22 decomposes under the heat of the UV light or the laser beam. The reconstructed wafer 44 may then be de-bonded from carrier 20.

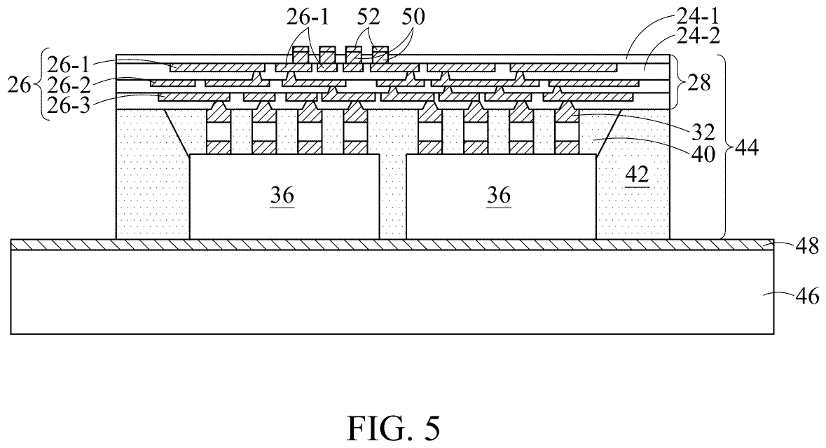

FIG. 5 illustrates the formation of electrical connectors 50 and solder regions 52. The respective process is illustrated as process 216 in the process flow 200 as shown in FIG. 25. In accordance with some embodiments, the formation process includes patterning the dielectric layer 24-1 in interconnect component 28 to reveal parts of the underlying portions of RDLs (such as RDLs 26-1), depositing a metal seed layer, forming a patterned plating mask (such as a photoresist), and plating the electric connectors 50 (which may be micro-bumps). When solder regions 52 are to be formed, solder regions 52 may also be plated. The patterned plating mask is then removed, followed by an etching process to remove the exposed portions of the metal seed layer. A reflow process may be performed to reflow solder regions 52.

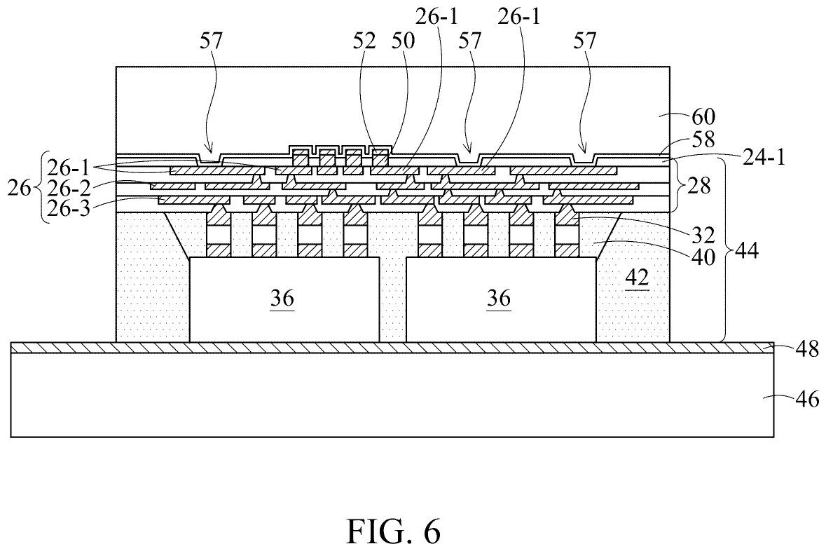

FIGS. 6 through 12 illustrate the formation of conductive features 70, which are larger and taller than micro-bumps 50. Referring to FIG. 6, openings are formed in dielectric layer 24-1 to expose the underlying metal pads 26-1, which are parts of RDLs 26-1. Metal seed layer 58 is formed, for example, through Physical Vapor Deposition (PVD) or metal foil lamination. The respective process is illustrated as process 218 in the process flow 200 as shown in FIG. 25. Metal seed layer 58 may be formed of or comprise copper, aluminum, titanium, alloys thereof, and/or multi-layers thereof. In accordance with some embodiments of the present disclosure, metal seed layer 58 includes a titanium layer (not separately shown) and a copper layer (not separately shown) over the titanium layer. In accordance with alternative embodiments, metal seed layer 58 includes a single copper layer. Metal seed layer 58 extends into openings 57 to contact metal pads 26-1. Metal seed layer 58 may also contact electrical connectors 50 and solder regions 52. Plating mask 60 is formed over metal seed layer 58. In accordance with some embodiments, plating mask 60 is or comprises a photoresist, and is referred to as photoresist 60 hereinafter. The respective process is illustrated as process 220 in the process flow 200 as shown in FIG. 25.

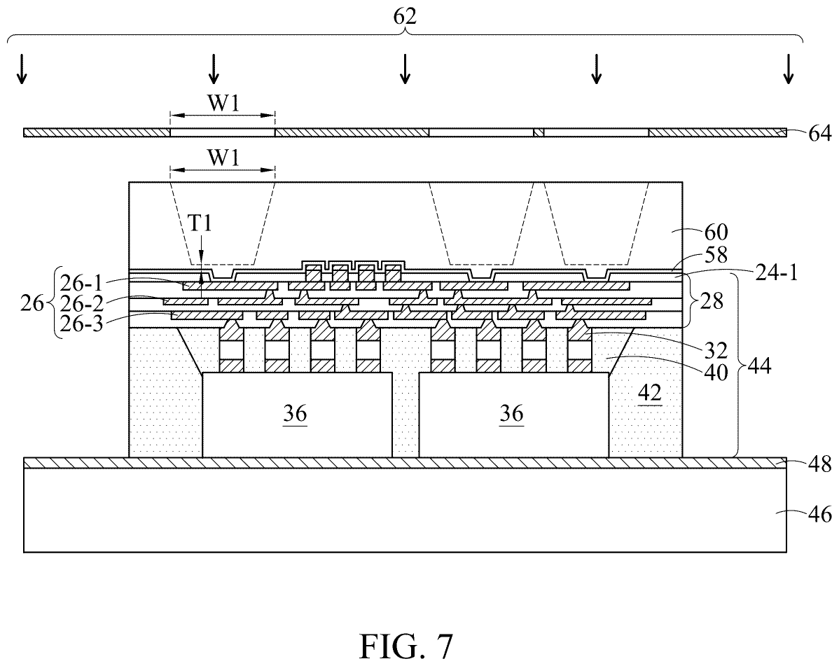

Referring to FIG. 7, a first light-exposure process 62 is performed using photolithography mask 64, which includes opaque portions for blocking light, and transparent portions allowing light to penetrate through. The respective process is illustrated as process 222 in the process flow 200 as shown in FIG. 25. photolithography mask 64 is used to expose photoresist 60, so that some parts of the photoresist 60 are light-exposed, while some other parts are not light-exposed. The illustrated process is shown assuming that photoresist 60 is a positive photoresist. Negative photoresist may also be used, with the opaque portions and transparent patterns in photolithography mask 64 being inverted.

The first light-exposure process 62 is configured so that some top portions of photoresist 60 are light-exposed, and some bottom portions of photoresist 60 directly underlying the exposed top portions remain not light-exposed. This may be achieved, for example, by adjusting the focus of the light beam to concentrate on the top portions, but not on the bottom portions, and/or by reducing the light intensity of the light used for exposing to certain level. In accordance with some embodiments, the width W1 of the exposed portions, which width W1 is also the width of the transparent portions of photolithography mask 64, may be in the range between about 70 μm and about 100 μm. The unexposed bottom portions of photoresist 60 have thickness T1, which may be greater than about 5 μm, and may be in the range between about 5 μm and about 50 μm.

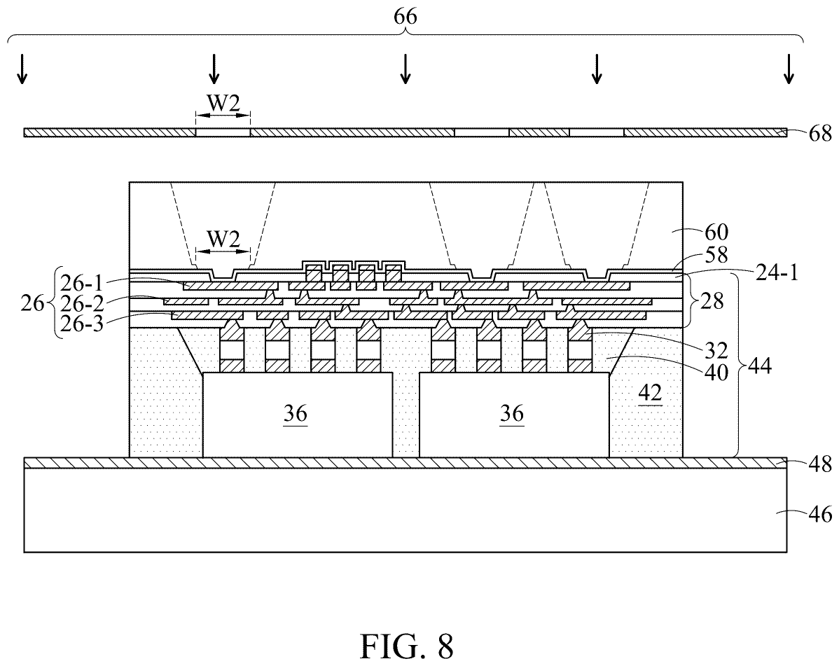

Referring to FIG. 8, a second light-exposure process 66 is performed using photolithography mask 68. The respective process is illustrated as process 224 in the process flow 200 as shown in FIG. 25. The second light-exposure process 66 may be configured so that some unexposed bottom portions of photoresist 60 are light-exposed. This may be achieved, for example, by extending the focus of the light beam to the bottom portions, and/or increasing the light intensity. In accordance with some embodiments, the width W2 of the exposed portions is smaller than the width W1 (FIG. 7) in photolithography mask 64. For example, width W2 may be in the range between about 40 μm and about 90 μm. The width difference (W1−W2) may be in the range between about 5 μm and about 50 μm. It is appreciated that the order of the first light-exposure process (using photolithography mask 64) and the second light-exposure process (using photolithography mask 68) may be inversed, and the second light-exposure process 66 may be performed before or after the first light-exposure process 62.

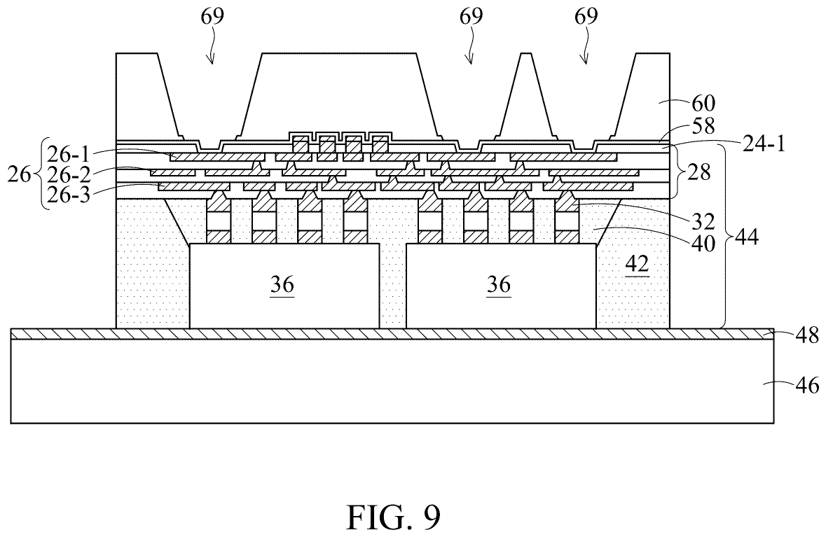

Photoresist 60 is then developed, as shown in FIG. 9. The respective process is illustrated as process 226 in the process flow 200 as shown in FIG. 25. Openings 69 are formed. The openings 69 have steps formed due to the light-exposure processes 62 and 64. Metal seed layer 58 is exposed/revealed to the openings 69.

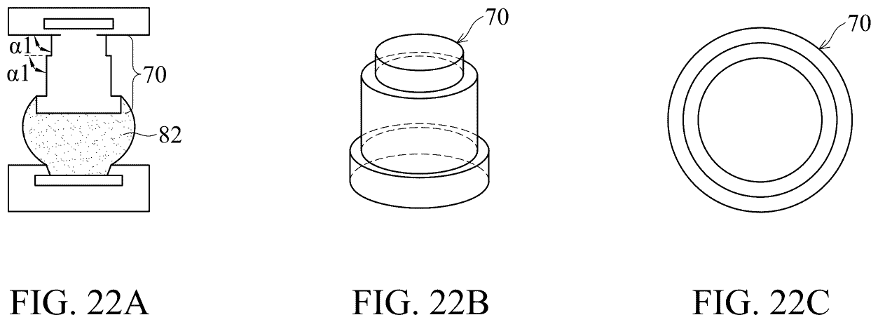

In above-discussed processes, two light-exposure processes are used. In accordance with alternative embodiments, multiple light-exposure processes, such as three, four or more light-exposure processes may be performed to form more steps. In the multiple light-exposure processes, different photolithography masks with the patterns having different widths are used, and the exposure process parameters such as the focus and light intensity are adjusted, so that two or more steps (FIGS. 22A, 22B, and 22C) may be formed. Furthermore, the multiple light-exposure processes may be performed in any order.

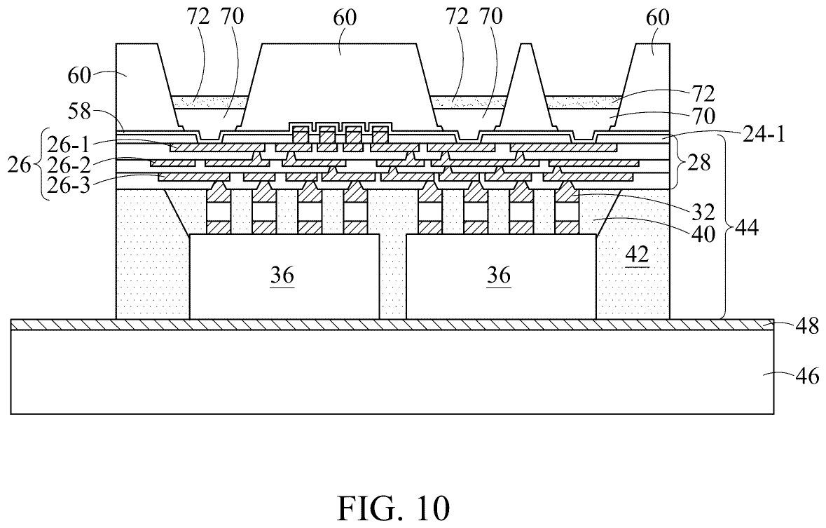

Next, as shown in FIG. 10, a plating process is performed, which may be performed through an electrochemical plating process, an electroless plating process, or the like. Electrical connectors 70 are thus formed. The respective process is illustrated as process 228 in the process flow 200 as shown in FIG. 25. In accordance with some embodiments, electrical connectors 70 are formed of or comprise copper, tungsten, nickel, gold, palladium, alloys thereof, and/or multi-layers thereof. Solder layers 72 may also be plated.

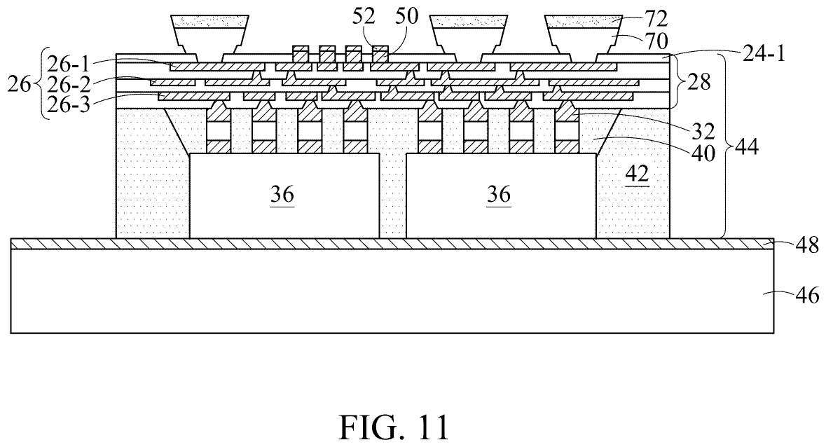

In subsequent processes, photoresist 60 is removed, for example, in an ashing process or an etching process. The respective process is illustrated as process 230 in the process flow 200 as shown in FIG. 25. Some portions of metal seed layer 58 are exposed, and are then removed through etching. The respective process is illustrated as process 232 in the process flow 200 as shown in FIG. 25. The portions of metal seed layer 58 directly underlying electrical connects 70 remain un-etched, and are considered as being parts of electrical connects 70. The resulting structure is shown in FIG. 11.

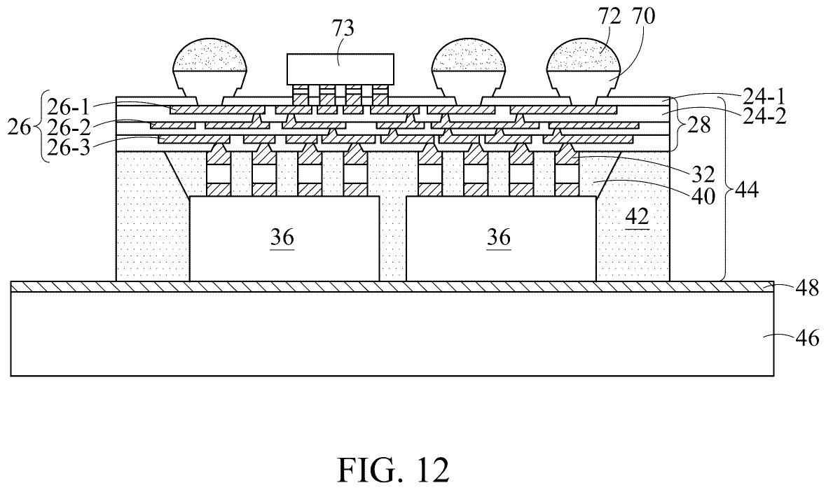

FIG. 12 illustrates the bonding of device die 73 to interconnect structure 28. The respective process is illustrated as process 234 in the process flow 200 as shown in FIG. 25. Device die 73 may be an IPD die, an active device die (including active devices), or the like. For example, when being an IPD die, device die 73 may include a capacitor(s), a resistor(s), a transmitter(s) therein. Solder layers 72 are also reflowed. In some embodiments, device die 73 may be connected to redistribution structure 28 after the solder layers 72 are reflowed.

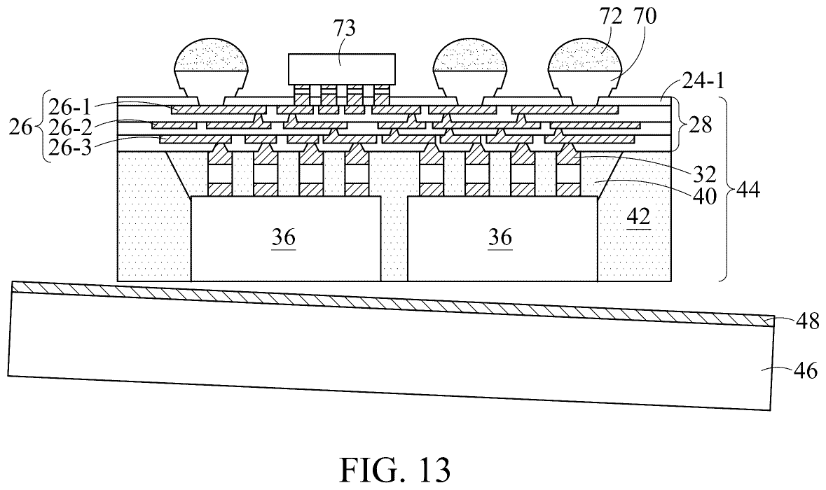

FIG. 13 illustrates a carrier de-bonding process. The respective process is illustrated as process 236 in the process flow 200 as shown in FIG. 25. Reconstructed wafer 44 is de-bonded from carrier 46, for example, by projecting UV light or a laser beam on release film 48 through carrier 46. Release film 48 decomposes under the heat of the UV light or the laser beam. The reconstructed wafer 44 may then be separated from carrier 46.

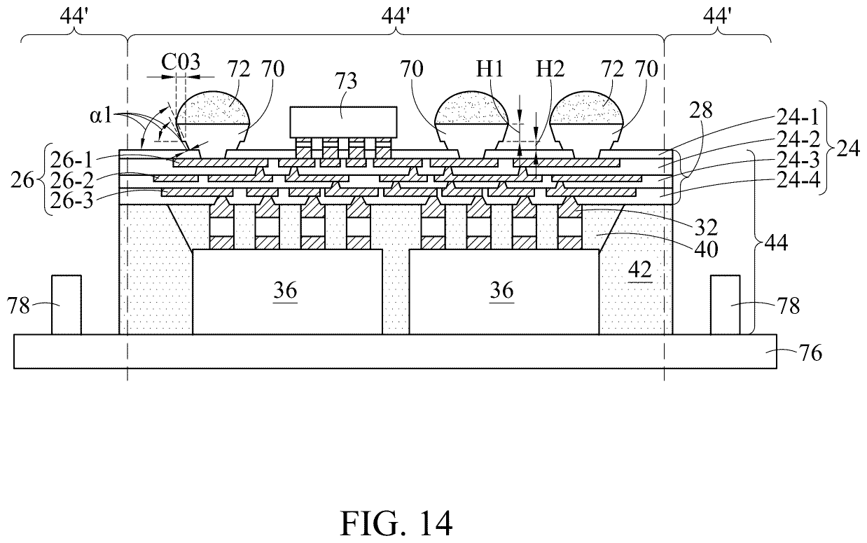

Referring to FIG. 14, reconstructed wafer 44 is placed on dicing tape 76, which is attached and fixed on frame 78. The reconstructed wafer 44 is then sawed in a singulation process, so that packages 44′, which are identical to each other, are separated from each other. The respective process is illustrated as process 238 in the process flow 200 as shown in FIG. 25.

In the resulting structure, the sidewalls of electrical connectors 70 have upper portions wider than lower portions. Furthermore, the sidewalls of electrical connectors 70 may form steps, with each formed by two slanted sidewalls, and a connecting portion (the illustrated bottom surface) interconnecting the slanted sidewalls. The width W3 of the interconnecting bottom surface may be greater than about 2 μm, and may be in the range between about 2 μm and about 15 μm. The heights H1 and H2 of the sidewalls of electrical connectors 70 may be in the range between about 5 μm and about 50 μm in accordance with some embodiments. The ratio H1/H2 may also be in the range between about ⅕ and about 5 in accordance with some embodiments.

The sidewalls of electrical connectors 70 may be vertical or may be slanted. Slant angles α1 of the sidewalls of electrical connectors 70 may be in the range between about 60 degrees and about 90 degrees, and may be in the range between about 60 degrees about 75 degrees. The reduction of the slant angles may be achieved through reducing the light-exposure power for light-exposure processes 62 and 66. The light-exposure power may be lower than about 150 mJ/cm² or lower than about 100 mJ/cm². The light-exposure power may also be in the range between about 50 mJ/cm² and about 150 mJ/cm².

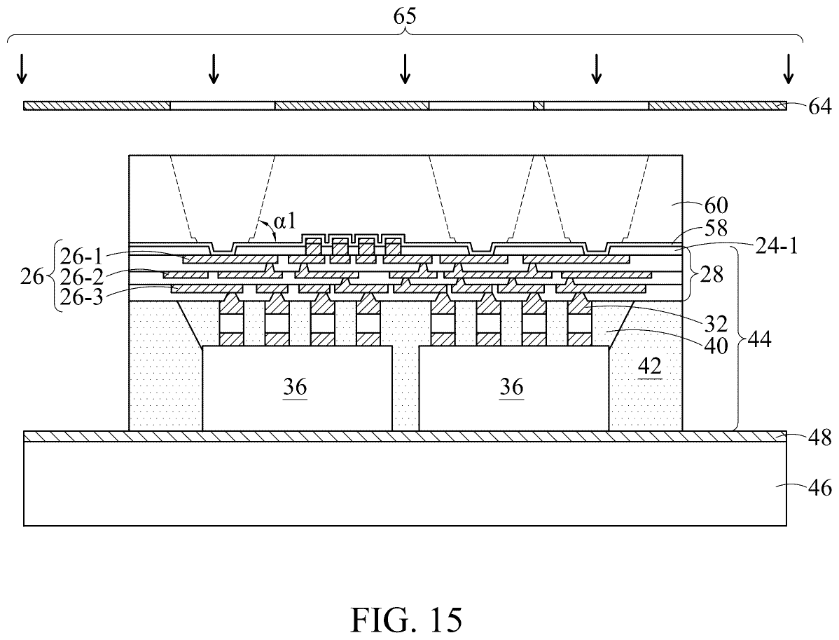

FIGS. 15 through 18 illustrate the cross-sectional views of intermediate stages in the formation of a package in accordance with some embodiments of the present disclosure. Unless specified otherwise, the materials and the formation processes of the components in these embodiments are essentially the same as the like components denoted by like reference numerals in the preceding embodiments shown in FIGS. 1 through 14. The details regarding the formation process and the materials of the components shown in FIGS. 15 through 18 may thus be found in the discussion of the preceding embodiments.

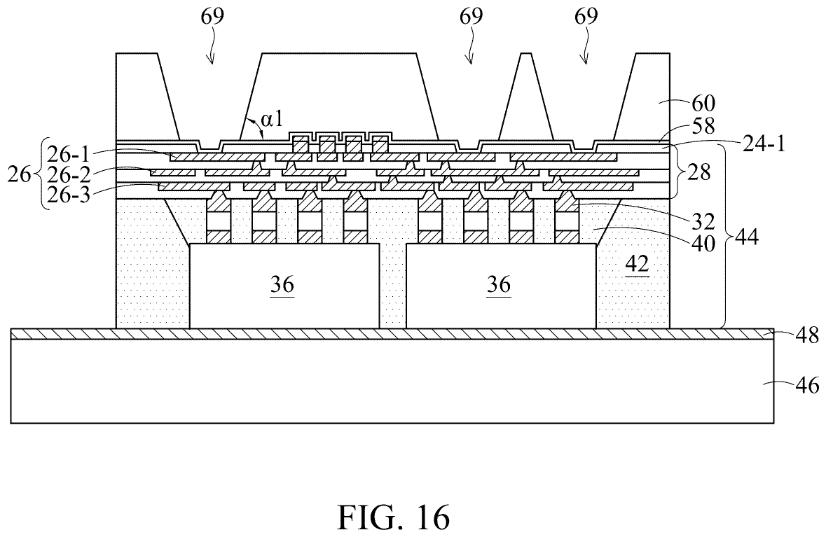

The initial processes of these embodiments are essentially the same as shown in FIGS. 1 through 6. Next, Referring to FIG. 15, light-exposure process 65 is performed using photolithography mask 64. In accordance with some embodiments, the light-exposure process 65 is performed using a low exposure power, for example, lower than about 200 mJ/cm² or lower than about 150 mJ/cm². The light-exposure power may also be in the range between about 100 mJ/cm² and about 200 mJ/cm². It has been found that the light-exposure power may affect the slant angle α1 of the sidewalls of the resulting opening 69 (FIG. 16), and the less the light-exposure power is, the smaller the tilt angle α1 will be. As will be discussed in subsequent paragraphs, smaller tilt angle α1 (hence more slanted sidewalls of the resulting electrical connectors) may help to increase standoff height of solder regions.

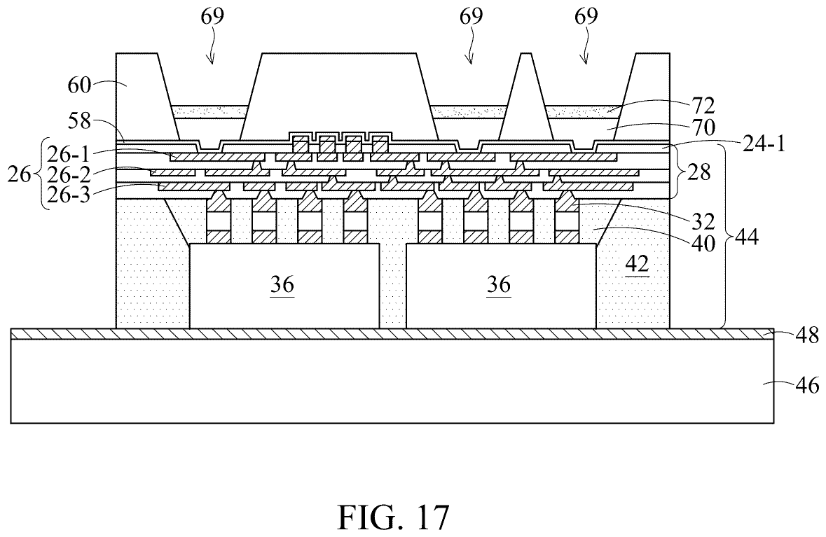

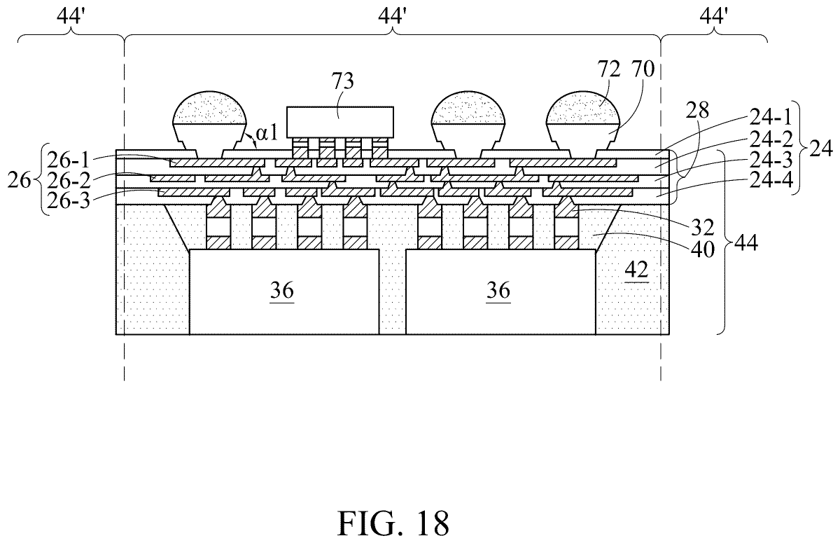

FIG. 16 illustrates the development of photoresist 60 to form openings 69, which have slanted sidewalls with slant angles α1, FIGS. 17 and 18 illustrate some subsequent processes, which are similar to what are shown in FIGS. 10 through 14, and are not repeated in detail hereinafter. As shown in FIG. 18, the sidewalls of electrical connectors 70 have slant angle α1. Slant angle α1 is small. In accordance with some embodiments, slant angle α1 is in the range between about 60 degrees and about 85 degrees, and may be in the range between about 60 degrees about 75 degrees. Slant angle α1 may be adjusted by adjusting the light-exposure power, as discussed in preceding paragraphs.

In accordance with yet alternative embodiments, the sidewall profile of electrical connectors 70 as shown in FIG. 18 may be formed through a plurality of light-exposure processes to form opening 69 in photoresist 60. The plurality of light-exposure processes may be similar to light-exposure processes 62 (FIG. 7) and 66 (FIG. 8), except more light-exposure processes (such as three, four, five, six, or more) may be performed. The portion of photoresist 60 exposed by the plurality of light-exposure processes are increasingly narrower and increasingly deeper. Also, the step widths (such as W3, FIG. 14) caused by the multiple light-exposure processes are small, and the steps at different heights may be the same as each other or different from each other. The step heights formed by the multiple light-exposure processes are small, and may be the same as each other or different from each other. Due to the small step widths and small step heights, the steps are smoothened, and the sidewall profile shown in FIG. 18 is formed.

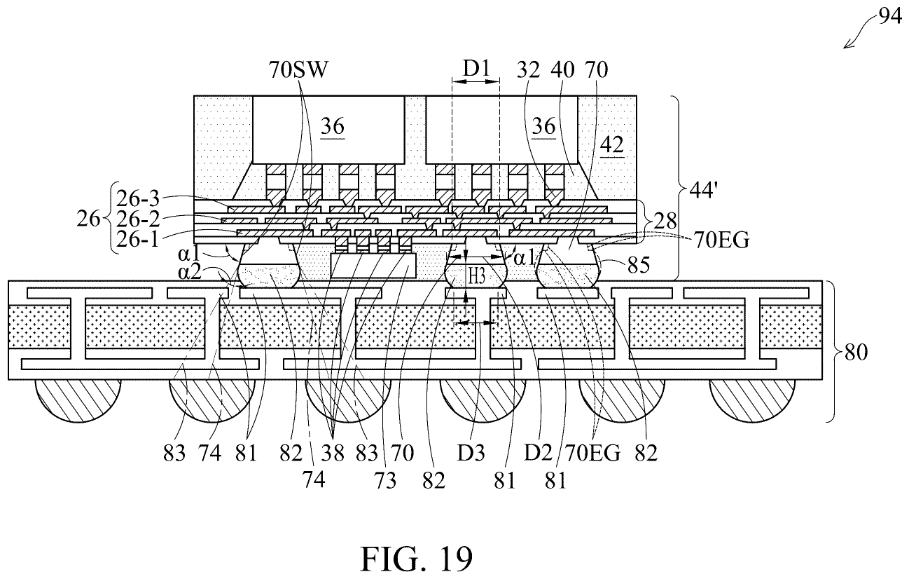

FIG. 19 illustrates the bonding of package 44′ (FIG. 14 or 18) on package component 80, so that package 94 is formed. The respective process is illustrated as process 240 in the process flow 200 as shown in FIG. 25. In accordance with some embodiments, package component 80 may be or may comprise a package substrate (cored or core-less), an interposer, a package including device dies therein, a device die, a printed circuit board, or the like. Solder regions 82, which may include the solder in solder regions 72 (FIGS. 14 and 18), are used for solder bonding, and are bonded to conductive features 81 in package component 80.

Solder regions 82 have sidewalls having tangent lines 83. The sidewalls 70SW of electrical connectors 70 have extension lines 74. Tangent lines 83 form angle α2 with the corresponding extension lines 74. It is appreciated that angle α2 affects the behavior of solder regions 82. When angle α2 is smaller than a characteristic angle, the entire solder regions 82 remain to be underlying the bottom surfaces of electrical connectors 70. When angle α2 is equal to or greater than the characteristic angle, solder regions 82 will be wetted on the sidewalls 70SW of electrical connectors 70, and will climb up sidewalls 70SW, until either the angle formed between tangent line 82 and the corresponding sidewall 70SW is smaller than the characteristic angle, or solder regions 82 meet dielectric layer 24. The characteristic angle is related to the materials of electrical connectors 70 and solder regions 82.

In accordance with some embodiments of the present disclosure, by forming electrical connectors 70 with small sidewall slant angles α1, sidewalls 70SW and extension lines 74 are more slanted. The angle α2 is reduced, and is more likely to be smaller than the characteristic angle. Solder regions 82 are thus less likely to climb up on the sidewalls 70SW. The standoff height H3 of solder regions 82 is thus increased compared if solder regions 82 climb up sidewalls 70SW.

In accordance with some embodiments in which electrically connectors 70 comprise steps (as shown by dashed sidewalls 70EG), solder regions 82 may climb up on the sidewalls 70SW of the first step of electrical connectors 70 when the bottom portions of sidewalls 70SW are slanted enough. In accordance with some embodiments, solder regions 82 may climb up on the sidewalls 70SW of the first step, but will stop on the top end of the sidewalls of the first step, wherein the dashed lines 85 illustrate the sidewalls of the corresponding solder regions 82 reaching the first step. At the top of the first step, since angle α2 becomes very big, solder regions 82 will stop there.

In accordance with some embodiments, the lateral dimension D1 (the top width as illustrated) of electrical connectors 70 may be in the range between about 50 μm and about 80 μm. The lateral dimension D2 (the bottom width as illustrated) of electrical connectors 70 is greater than lateral dimension D1, so that angle α1 is small. Lateral dimension D2 may be in the range between about 70 μm and about 100 μm. The difference (D1−D2) may be in the range between about 5 μm and about 50 μm in accordance with some embodiments. A ratio D1/D2 may also be smaller than about 0.9, and may be in the range between about 0.5 and about 0.9. The lateral dimension D3 of solder regions measured at the top surface level of package component 80 is smaller than lateral dimension D2, so that angle α2 is kept small. In accordance with some embodiments, lateral dimension D3 may be in the range between about 50 μm and about 80 μm.

In accordance with some embodiments, by forming electrical connectors 70 whose sidewalls have selected profiles, all of the solder regions 82 in the entire package 94 will not climb on the sidewalls of the respective overlying electrical connectors 70, and will be under the bottom surfaces of electrical connectors 70, or climb on the sidewalls of electrical connectors, but are kept below the bottom step.

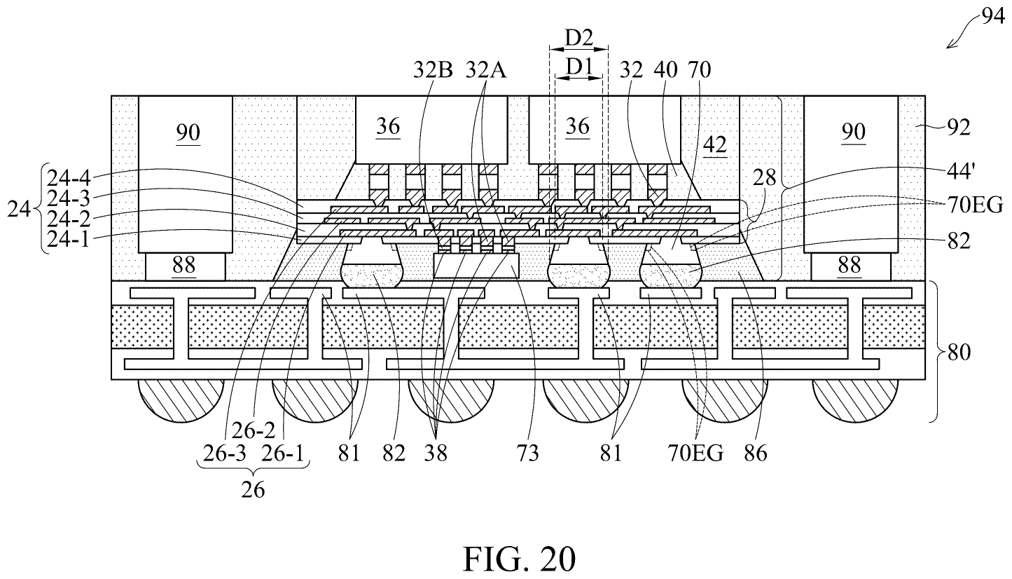

FIG. 20 illustrates the continued packaging process for forming package 94. The continued packaging process may include dispensing underfill 86 into the gap between package 44′ and package component 80, attaching stiffener ring 90 to package component 80 through adhesive films 88, and encapsulating package 44′ and stiffener ring 90 in encapsulant 92, which may be a molding compound.

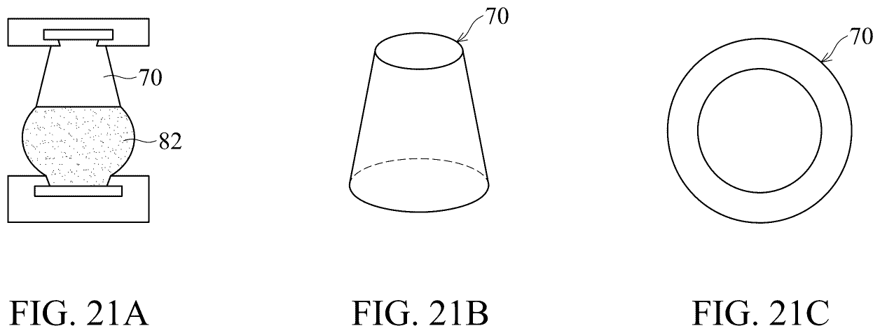

The electrical connector 70 (FIGS. 14, 18, and 20) may have various profiles. FIGS. 21A, 21B, and 21C illustrate a cross-sectional view, a perspective view, and a bottom view, respectively, of a cone-shaped electrical connector 70 in accordance with some embodiments. Both of the top end and the bottom end of electrical connector 70 have round shapes.

FIGS. 22A, 22B, and 22C illustrate a cross-sectional view, a perspective view, and a bottom view, respectively, of a cake-shaped electrical connector 70 in accordance with some embodiments. The cake-shaped electrical connector 70 includes a plurality of steps. In the illustrated example, two steps are formed, while electrical connector 70 may also have a single or more than two steps. Each of the steps may act as a barrier to prevent solder from climbing up. The sidewalls of the multiple steps may be vertical or may be slanted, as shown in FIG. 14. The slant angles α1 may be similar to what have been discussed in preceding embodiments. In addition, in the example as shown in FIG. 22A, solder regions 82 climbs to the first step of the sidewall of electrical connector 70.

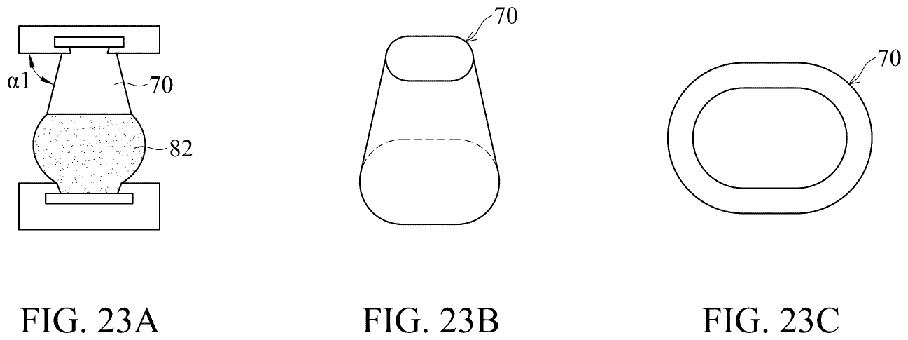

FIGS. 23A, 23B, and 23C illustrate a cross-sectional view, a perspective view, and a bottom view, respectively, of an oval cone-shaped electrical connector 70 in accordance with some embodiments. Both of the top end and the bottom end of electrical connector 70 may have oval shapes.

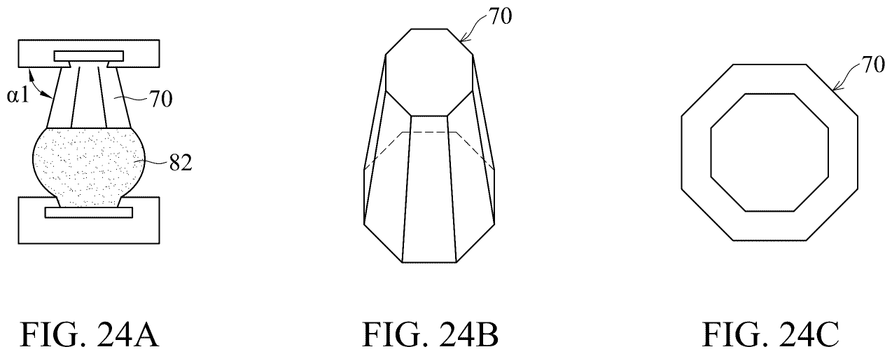

FIGS. 24A, 24B, and 24C illustrate a cross-sectional view, a perspective view, and a bottom view, respectively, of an oval pyramidal frustum shaped electrical connector 70 in accordance with some embodiments. Both of the top end and the bottom end of electrical connector 70 may have polygon shapes such as hexagon shapes, octagon shapes, or the like.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming the electrical connectors with the ends contacting solder regions being wider than the opposite ends, the wetting of solder on the sidewalls of the electrical connectors is prevented. Accordingly, solder regions have higher standoff heights. This allows more room for having IPD dies, and the IPD dies will not in contact with the neighboring package components.

In accordance with some embodiments of the present disclosure, a method comprises forming a first package component comprising a conductive feature, and a dielectric layer covering the conductive feature; forming a first opening in the dielectric layer, wherein the conductive feature is exposed to the first opening; forming a metal seed layer on the dielectric layer, wherein the metal seed layer extends into the first opening to contact the conductive feature; forming a plating mask over the metal seed layer, with a second opening formed in the plating mask, wherein the first opening is joined to the second opening; plating a conductive material into the first opening and the second opening; removing the plating mask to expose portions of the metal seed layer; and etching the portions of the metal seed layer, wherein the conductive material and a remaining portion of the metal seed layer collectively form a metal pillar over the dielectric layer, and wherein the metal pillar has a top width and a bottom width smaller than the top width, with the bottom width being measured at a surface level of the dielectric layer.

In an embodiment, the method further comprises bonding a second package component to the first package component, with the second package component being underlying the first package component, wherein a solder region joins the metal pillar to the second package component, and wherein an entirety of the solder region is underlying the metal pillar. In an embodiment, the method further comprises forming a micro-bump on the first package component, wherein the micro-bump has a first height smaller than a second height of the metal pillar; and bonding a passive device die to the first package component through the micro-bump. In an embodiment, the forming the plating mask comprises performing a first light-exposure process on the plating mask using a first lithography mask, wherein a first portion of the plating mask is light-exposed; and performing a second light-exposure process on the plating mask using a second lithography mask, wherein a second portion of the plating mask is light-exposed; and performing a development process on the plating mask.

In an embodiment, the first portion and the second portion of the plating mask have different widths. In an embodiment, the first portion is wider than the second portion, and wherein the second portion is deeper than the first portion. In an embodiment, the first portion and the second portion of the plating mask have different depths. In an embodiment, the first portion and the second portion of the plating mask include a common portion of the plating mask. In an embodiment, the second opening comprises an upper portion and a lower portion, wherein the lower portion is narrower than the upper portion, and wherein the upper portion and the lower portion form a step. In an embodiment, the metal pillar comprises a sidewall forming a tilt angle with a top surface of the dielectric layer, and wherein the tilt angle is smaller than about 85 degrees. In an embodiment, a ratio of the bottom width to the top width is smaller than about 0.9.

In accordance with some embodiments of the present disclosure, a package comprises a first package component comprising a bottom dielectric layer; a micro-bump protruding below the bottom dielectric layer; and a metal pillar protruding below the bottom dielectric layer, wherein the metal pillar has a top width and a bottom width greater than the top width; a die underlying and bonding to the micro-bump; a solder region underlying and joining to a bottom surface of the metal pillar; and a second package component underlying the first package component, wherein the second package component comprising a conductive feature underlying and joining to the solder region. In an embodiment, a topmost end of the solder region is at substantially a same level as the bottom surface of the metal pillar. In an embodiment, the metal pillar comprises an upper portion, and a lower portion wider than the upper portion, and wherein a first sidewall of the upper portion and a second sidewall of the lower portion form a step. In an embodiment, the solder region extends to a topmost end of the second sidewall of the lower portion. In an embodiment, the solder region is spaced apart from the first sidewall of the upper portion.

In accordance with some embodiments of the present disclosure, a package comprises a package component comprising a bottom dielectric layer; a metal pillar comprising a first portion lower than a bottom surface of the bottom dielectric layer; and a second portion underlying and joining to the first portion, wherein the second portion is wider than the first portion, and wherein a first sidewall of the first portion and a second sidewall of the second portion form a first step. In an embodiment, the package further comprises a solder region underlying and joining to an additional bottom surface of the metal pillar, wherein the solder region extends to a top end of the second portion of the metal pillar. In an embodiment, the metal pillar further comprises a third portion over the first portion, wherein the third portion forms a second step with the first portion of the metal pillar. In an embodiment, the first sidewall and the second sidewall are discontinuous from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a first package component comprising:
a bottom dielectric layer;
a micro-bump protruding below the bottom dielectric layer; and
a metal pillar protruding below the bottom dielectric layer, wherein the metal pillar has a top width and a bottom width greater than the top width;
a die underlying and bonding to the micro-bump;
a solder region underlying and joining to a bottom surface of the metal pillar; and
a second package component underlying the first package component, wherein the second package component comprising a conductive feature underlying and joining to the solder region.

2. The package of claim 1, wherein a topmost end of the solder region is at substantially a same level as the bottom surface of the metal pillar.

3. The package of claim 1, wherein the metal pillar comprises an upper portion, and a lower portion wider than the upper portion, and wherein a first sidewall of the upper portion and a second sidewall of the lower portion form a step.

4. The package of claim 3, wherein the solder region extends to a topmost end of the second sidewall of the lower portion.

5. The package of claim 3, wherein the solder region is spaced apart from the first sidewall of the upper portion.

6. The package of claim 3, wherein the first sidewall is tilted.

7. The package of claim 6, wherein the second sidewall is tilted.

8. The package of claim 6, wherein the first sidewall and the second sidewall have substantially a same tilt angle.

9. The package of claim 1, wherein a sidewall of the metal pillar comprises:
a first step; and
a second step lower than the first step.

10. A package comprising:
a package component comprising:
a bottom dielectric layer;
a metal pillar comprising:
a first portion lower than a bottom surface of the bottom dielectric layer; and
a second portion underlying and joining to the first portion, wherein the second portion is wider than the first portion, and wherein a first sidewall of the first portion and a second sidewall of the second portion form a first step.

11. The package of claim 10 further comprising:
a solder region underlying and joining to an additional bottom surface of the metal pillar, wherein the solder region extends to a top end of the second portion of the metal pillar.

12. The package of claim 10, wherein the metal pillar further comprises a third portion over the first portion, wherein the third portion forms a second step with the first portion of the metal pillar.

13. The package of claim 10, wherein the first sidewall and the second sidewall are discontinuous from each other.

14. The package of claim 10, wherein the firs sidewall is tilted.

15. The package of claim 14, wherein the second sidewall is tilted and has substantially a same tilt angle as the first sidewall.

16. The package of claim 10, wherein the package component further comprises:
a redistribution structure comprising a plurality of dielectric layers and a plurality of redistribution lines in the plurality of dielectric layers, wherein the bottom dielectric layer is comprised in the plurality of dielectric layers; and
a device die over and electrically coupled to the metal pillar through the plurality of redistribution lines.

17. A package comprising:
a package substrate comprising conductive features therein;
a solder region over and electrically connected to one of the conductive features;
a metal pillar over and joined to the solder region, wherein an entirety of the metal pillar is higher than the solder region, and wherein the metal pillar comprises:
a lower section comprising a first sidewall and a top surface; and
an upper section over and joined to the lower section, wherein the upper section comprises a second sidewall;
a redistribution structure over and joined to the metal pillar; and
a device die over the redistribution structure, wherein the device die is electrically connected to the metal pillar through the redistribution structure.

18. The package of claim 17 further comprising an underfill in physical contact with the first sidewall, the top surface, and the second sidewall.

19. The package of claim 17, wherein the metal pillar comprises copper.

20. The package of claim 17, wherein the first sidewall and the second sidewall are straight sidewalls.
